(19) United States
(12) Patent Application Publication
(10) Pub. No.: US 2024/0186247 A1
(43) Pub. Date: Jun. 6, 2024

(54) SEMICONDUCTOR DEVICE AND METHOD FOR MANUFACTURING THE SEMICONDUCTOR DEVICE

(71) Applicant: SAMSUNG ELECTRONICS CO., LTD., Suwon-si (KR)

(72) Inventors: Hyung Jun JEON, Suwon-si (KR); Ho-Jin Lee, Suwon-si (KR)

(21) Appl. No.: 18/211,316

(22) Filed: Jun. 19, 2023

(30) Foreign Application Priority Data
Dec. 2, 2022 (KR) 10-2022-0166631

(51) Int. Cl. H01L 23/528; H01L 23/48; H01L 27/06; H01L 29/417

(52) U.S. Cl. CPC H01L 23/5286; H01L 23/481; H01L 27/0629; H01L 28/40; H01L 29/41766

(57) ABSTRACT

A semiconductor device includes: a substrate including a first face, on which an active area is formed, and a second face opposite to the first face; an electronic element formed on the active area; a front wiring structure disposed on the first face of the substrate and connected to the electronic element; a trench capacitor filling at least a portion of a back trench extending into the substrate from the second face of the substrate; a back wiring structure disposed on the second face of the substrate and connected to the trench capacitor; and a through-via extending through the substrate to electrically connect the electronic element and the back wiring structure to each other.

### CROSS-REFERENCE TO RELATED APPLICATION

This application claims priority under 35 USC § 119 to Korean Patent Application No. 10-2022-0166631 filed on Dec. 2, 2022, in the Korean Intellectual Property Office, the disclosure of which is incorporated by reference herein in its entirety.

### TECHNICAL FIELD

The present inventive concept relates to a semiconductor device and a method for manufacturing the semiconductor device. More specifically, the present inventive concept relates to a semiconductor device including a back wiring pattern and a method for manufacturing the semiconductor device.

### DISCUSSION OF THE RELATED ART

Due to characteristics such as miniaturization, multifunctionality, and/or a low manufacturing cost of a semiconductor device, the semiconductor device is an important element in the electronics industry. Semiconductor devices may be classified as a semiconductor memory device that stores therein logic data, a semiconductor logic device that computes logic data, and a hybrid semiconductor device including a memory element and a logic element.

As the electronics industry continues to develop, demand for further development of characteristics of the semiconductor device continues to increase. For example, demand for high reliability, high speed, and/or multifunctionality of the semiconductor device is gradually increasing. To meet this demand, structures in the semiconductor device are becoming increasingly complex and highly integrated.

### SUMMARY

According to an embodiment of the present inventive concept, a semiconductor device includes: a substrate including a first face, on which an active area is formed, and a second face opposite to the first face; an electronic element formed on the active area; a front wiring structure disposed on the first face of the substrate and connected to the electronic element; a trench capacitor filling at least a portion of a back trench extending into the substrate from the second face of the substrate; a back wiring structure disposed on the second face of the substrate and connected to the trench capacitor; and a through-via extending through the substrate to electrically connect the electronic element and the back wiring structure to each other.

According to an embodiment of the present inventive concept, a semiconductor device includes: a substrate including a first face, on which an active area is formed, and a second face opposite to the first face; a first electronic element formed on the active area; a first through-via extending through the substrate to be electrically connected to the first electronic element; a trench capacitor filling at least a portion of a back trench extending into the substrate from the second face of the substrate; and a back wiring structure disposed on the second face of the substrate, wherein the back wiring structure electrically connects the first through-via and the trench capacitor to each other, wherein a first power voltage is applied to the first electronic element and the trench capacitor via the back wiring structure.

According to an embodiment of the present inventive concept, a semiconductor device includes: a substrate including a first face, on which a first active area and a second active area are formed, and a second face opposite to the first face; a first electronic element disposed on the first active area and having a first conductivity type; a second electronic element disposed on the second active area and having a second conductivity type different from the first conductivity type; a front wiring structure disposed on the first face of the substrate, and connected to the first electronic element and the second electronic element; a first through-via extending through the substrate and electrically connected to the first electronic element; a second through-via extending through the substrate and electrically connected to the second electronic element; a trench capacitor filling at least a portion of a back trench extending into the substrate from the second face of the substrate, wherein the trench capacitor includes a first electrode film and a second electrode film facing each other; and a back wiring structure disposed on the second face of the substrate, wherein the back wiring structure connects the first through-via and the first electrode film to each other and connect the second through-via and the second electrode film to each other.

### BRIEF DESCRIPTION OF DRAWINGS

The above and features of the present inventive concept will become more apparent by describing in detail embodiments thereof with reference to the attached drawings, in which:

FIG. 1 is an illustrative layout diagram for illustrating a semiconductor device according to an embodiment of the present inventive concept.

FIG. 2 is a schematic cross-sectional view taken along A-A of FIG. 1.

FIG. 3A and FIG. 3B are various enlarged views to illustrate an R area of FIG. 2.

FIG. 4 is a schematic cross-sectional view taken along B-B of FIG. 1.

FIG. 5 is a schematic cross-sectional view taken along C-C of FIG. 1.

FIG. 6A to FIG. 6C are illustrative perspective views for illustrating a trench capacitor of FIG. 2.

FIG. 7 is a schematic cross-sectional view for illustrating a semiconductor device according to an embodiment of the present inventive concept.

FIG. 8 is a schematic cross-sectional view for illustrating a semiconductor device according to an embodiment of the present inventive concept.

FIG. 9 is a schematic cross-sectional view for illustrating a semiconductor device according to an embodiment of the present inventive concept.

FIG. 10 and FIG. 11 are schematic cross-sectional views for illustrating a semiconductor device according to an embodiment of the present inventive concept.

FIGS. 12, 13, 14, 15, 16, 17, 18, 19 and FIG. 20 are diagrams of intermediate structures corresponding to intermediate steps for illustrating a method for manufacturing a semiconductor device according to an embodiment of the present inventive concept.

FIG. 21 is a diagram of an intermediate structure corresponding to an intermediate step for illustrating a method for manufacturing a semiconductor device according to an embodiment of the present inventive concept.

FIGS. 22, 23, 24, 25 and 26 are diagrams of intermediate structures corresponding to intermediate steps for illustrating a method for manufacturing a semiconductor device according to an embodiment of the present inventive concept.

### DETAILED DESCRIPTIONS OF EMBODIMENTS

For simplicity and clarity of illustration, elements in the drawings are not necessarily drawn to scale. The same reference numbers in different drawings represent the same or similar elements throughout the specification and drawings, and as such perform similar functionality. Examples of various embodiments are illustrated and described further below. It is to be understood that the present inventive concept may, however, be embodied in different forms and thus should not be construed as being limited to the exemplary embodiments set forth herein.

As used herein, the singular forms “a” and “an” are intended to include the plural forms as well, unless the context clearly indicates otherwise. As used herein, the term “and/or” includes any and all combinations of one or more of the associated listed items. When referring to “C to D”, this means C inclusive to D inclusive unless otherwise specified.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present inventive concept.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or another layer, film, region, plate, or the like may be disposed between the former and the latter. As used herein, when a layer, film, region, plate, or the like is directly disposed “on” or “on a top” of another layer, film, region, plate, or the like, the former directly contacts the latter and another layer, film, region, plate, or the like is not disposed between the former and the latter. Further, as used herein, when a layer, film, region, plate, or the like may be disposed “below” or “under” another layer, film, region, plate, or the like, the former may directly contact the latter or another layer, film, region, plate, or the like may be disposed between the former and the latter. As used herein, when a layer, film, region, plate, or the like is directly disposed “below” or “under” another layer, film, region, plate, or the like, the former directly contacts the latter and another layer, film, region, plate, or the like is not disposed between the former and the latter.

When an embodiment of the present invention may be implemented differently, a process order may be performed differently from the described order. For example, two consecutively described processes may be performed at substantially the same time or performed in an order opposite to the described order.

In descriptions of temporal relationships, for example, temporal precedent relationships between two events such as “after”, “subsequent to”, “before”, etc., another event may occur therebetween unless “directly after”, “directly subsequent” or “directly before” is indicated. The features of the various embodiments of the present inventive concept may be partially or entirely combined with each other, and may be technically associated with each other or operate with each other. The embodiments may be implemented independently of each other and may be implemented together in an association relationship. Spatially relative terms, such as “beneath,” “below,” “lower,” “under,” “above,” “upper,” and the like, may be used herein for ease of explanation to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

Terms as used herein “first direction X”, “second direction Y” and “third direction Z” should not be interpreted only to have a geometric relationship in which the first direction, the second direction, and the third direction cross each other (e.g., are perpendicular to each other). The “first direction X”, “second direction Y” and “third direction Z” may be interpreted to have a broader direction in a range in which components herein may work functionally.

In the present disclosure, a field effect transistor (FET) is illustrated as an example of an electronic element included in a semiconductor device. However, this is an example. In another example, the semiconductor device includes a system LSI (large scale integration), a flash memory, a DRAM, a SRAM, an EEPROM, a PRAM, a MRAM or a RERAM, an image sensor such as a CIS (CMOS imaging sensor), a MEMS (micro-electro-mechanical system), an active element, a passive element, or etc.

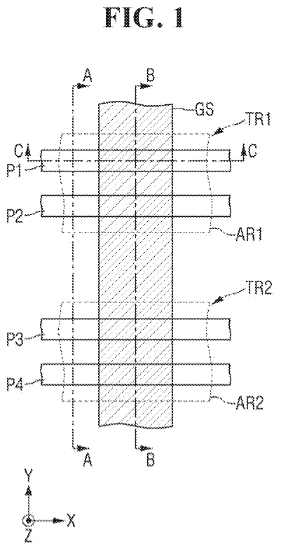

Hereinafter, referring to FIG. 1 to FIG. 11, a semiconductor device according to some embodiments of the present inventive concept is described.

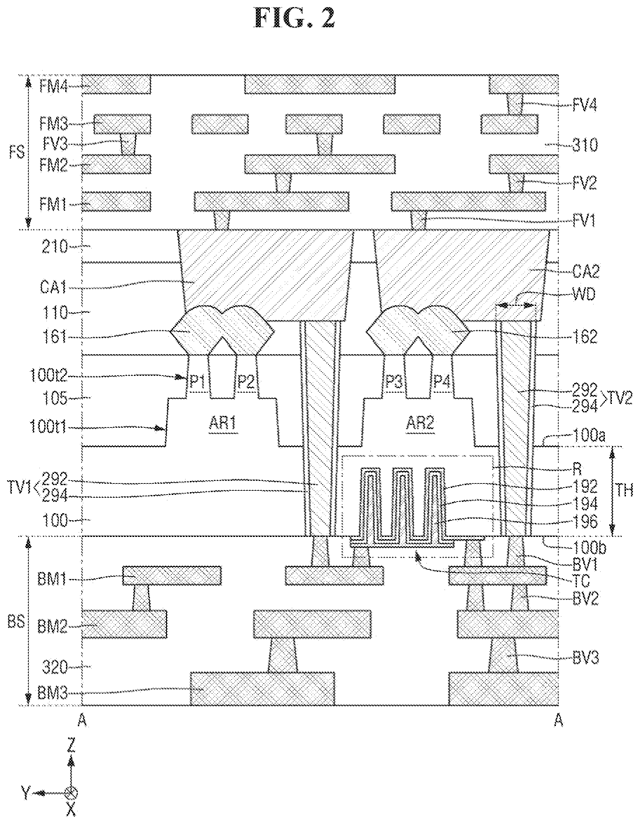

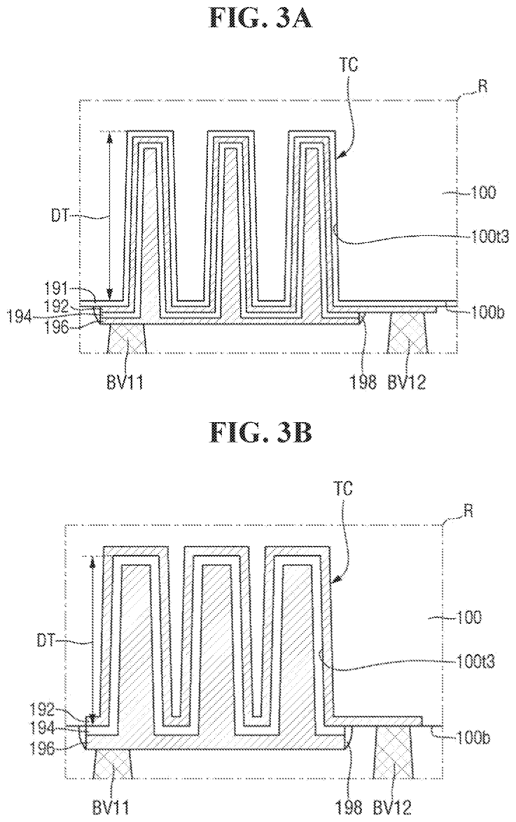

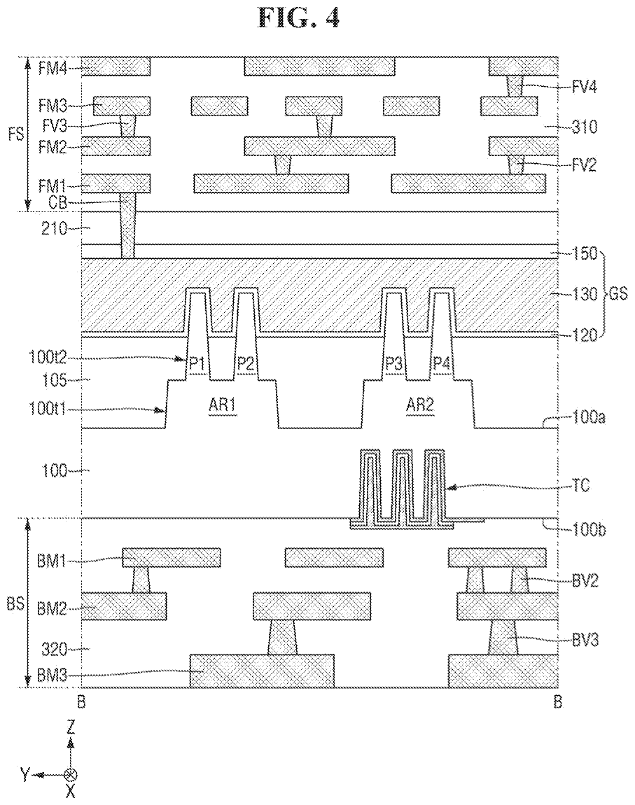

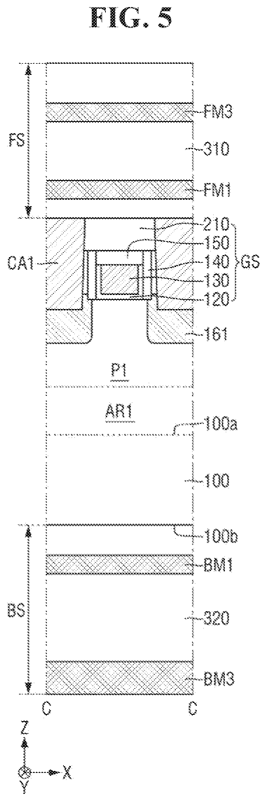

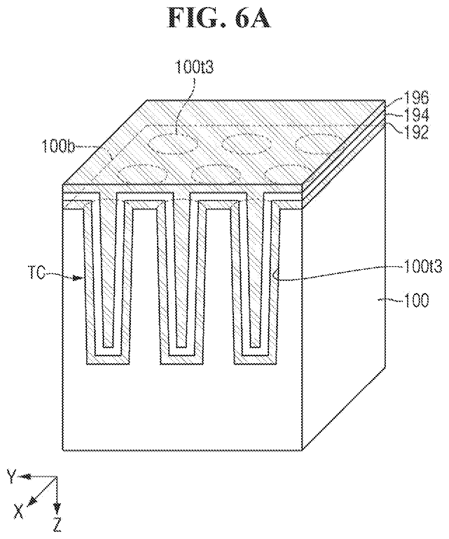

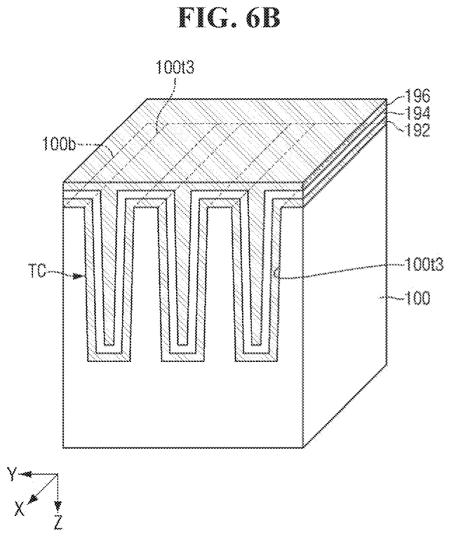

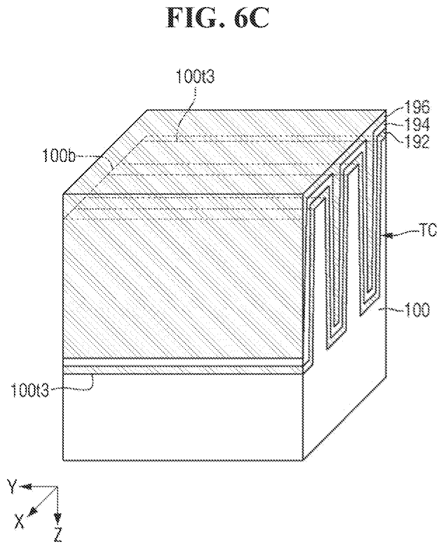

FIG. 1 is an illustrative layout diagram for illustrating a semiconductor device according to an embodiment of the present inventive concept. FIG. 2 is a schematic cross-sectional view taken along A-A of FIG. 1. FIG. 3A and FIG. 3B are various enlarged views to illustrate an R area of FIG. 2. FIG. 4 is a schematic cross-sectional view taken along B-B of FIG. 1. FIG. 5 is a schematic cross-sectional view taken along C-C of FIG. 1. FIG. 6A to FIG. 6C are illustrative perspective views for illustrating a trench capacitor of FIG. 2.

Referring to FIG. 1 to FIG. 6C, the semiconductor device according to some embodiments of the present inventive concept includes a substrate 100, a first electronic element TR1, a second electronic element TR2, interlayer insulating films 110 and 210, a front wiring structure FS, a trench capacitor TC, a back wiring structure BS, a first through-via TV1 and a second through-via TV2.

The substrate 100 may be made of a bulk silicon or SOI (silicon-on-insulator). In addition, as an example, the substrate 100 may be a silicon substrate, or may include a material other than silicon, such as silicon germanium, SGOI (silicon germanium on insulator), indium antimonide, a lead telluride compound, indium arsenide, indium phosphide, gallium arsenide, or gallium antimonide. However, the present inventive concept is not limited thereto.

The substrate 100 may include a first active area AR1 and a second active area AR2. Although the first active area AR1 and the second active area AR2 are illustrated as being adjacent to each other, this is an example, and the first active area AR1 and the second active area AR2 may be spaced apart from each other. Each of the first active area AR1 and the second active area AR2 may be defined by a first element isolation trench 100t1 in the substrate 100. The first element isolation trench 100t1 may be a deep trench formed in the substrate 100. For example, the first element isolation trench 100t1 may extend in the first direction X parallel to a top face of the substrate 100 so as to isolate the first active area AR1 and the second active area AR2 from each other.

As used herein, a surface (for example, the top face of the substrate 100) of the substrate 100 on which the first active area AR1 and the second active area AR2 are formed may be referred to as a first face 100a or a front face. In addition, a surface (for example, a bottom face of the substrate 100) of the substrate 100 opposite to the front face or the first face 100a of the substrate 100 may be referred to as a second face 100b or a back face of the substrate 100.

In some embodiments of the present inventive concept, electronic elements of different conductivity types (for example, field effect transistors) may be formed on the first active area AR1 and the second active area AR2, respectively. For example, the first electronic element TR1 having a first conductivity type may be formed on the first active area AR1, while the second electronic element TR2 having a second conductivity type different from the first conductivity type may be formed on the second active area AR2. In following description, an example in which the first conductivity type is a p-type, and the second conductivity type is an n-type is described. In one example, the first active area AR1 may be a PFET area, and the second active area AR2 may be an NFET area. However, this is an example, and the first conductivity type may be the n-type and the second conductivity type may be the p-type.

In some embodiments of the present inventive concept, the first electronic element TR1 may include a first active pattern P1 and P2, a gate structure GS, and a first source/drain area 161. The second electronic element TR2 may include a second active pattern P3 and P4, the gate structure GS, and a second source/drain area 162. It is illustrated that the first electronic element TR1 and the second electronic element TR2 share the gate structure GS. However, this is only an example. In another example, the gate structure GS of the first electronic element TR1 and the gate structure GS of the second electronic element TR2 might not be electrically connected to each other.

The first active pattern P1 and P2 may be formed on the top face of the first active area AR1. The first active pattern P1 and P2 may extend in the first direction X. The first active pattern P1 and P2 are illustrated as including two sub-patterns (for example, a first sub-pattern P1 and a second sub-pattern P2 which are spaced apart from each other and extend side by side). This is an example, and the number of sub-patterns included in the first active pattern P1 and P2 may vary.

The second active pattern P3 and P4 may be formed on the top face of the second active area AR2. The second active pattern P3 and P4 may extend in the first direction X. The second active pattern P3 and P4 are illustrated as including two sub-patterns (for example, a third sub-pattern P3 and a fourth sub-pattern P4 which are spaced apart from each other and extending side by side). This is an example, and the number of sub-patterns included in the second active pattern P3 and P4 may vary.

In some embodiments of the present inventive concept, each of the active patterns P1 to P4 may include a fin pattern. For example, the first active pattern P1 and P2 may protrude from the top face of the first active area AR1 and extend in the first direction X. The second active pattern P3 and P4 may protrude from the top face of the second active area AR2 and extend in the first direction X. Each of the active patterns P1 to P4 may be defined by a second element isolation trench 100t2. The second element isolation trench 100t2 may be a shallow trench formed in the substrate 100. For example, the second element isolation trench 100t2 may extend in the first direction X to isolate the active patterns P1 to P4 from each other.

In some embodiments of the present inventive concept, a field insulating film 105 may be formed on the substrate 100. The field insulating film 105 may surround at least a portion of a side face of each of the active patterns P1 to P4. For example, as shown in FIG. 2 and FIG. 4, a portion of each of the active patterns P1 to P4 may protrude upward beyond the field insulating film 105. Further, the field insulating film 105 may fill the first element isolation trench 100t1. For example, the first active area AR1 and the second active area AR2 may be isolated from each other via the field insulating film 105.

The field insulating film 105 may include, for example, at least one of silicon oxide (SiO₂), silicon oxynitride (SiON), silicon oxycarbonitride (SiOCN), or a combination thereof. However, the present inventive concept is not limited thereto.

The gate structure GS may be formed on the first active pattern P1 and P2 and/or the second active pattern P3 and P4. The gate structure GS may intersect the first active pattern P1 and P2 and/or the second active pattern P3 and P4.

For example, the gate structure GS may extend in the second direction Y, which is parallel to the top face of the substrate 100 and intersects the first direction X. In some embodiments of the present inventive concept, the gate structure GS may include a gate dielectric film 120, a gate electrode 130, a gate spacer 140, and a gate capping pattern 150.

The gate electrode 130 may extend in the second direction Y while being disposed on the field insulating film 105, the first active pattern P1 and P2 and/or the second active pattern P3 and P4. The gate electrode 130 may include a conductive material, for example, at least one of (Ti), (Ta), (W), (Al), (Co), or combinations thereof. However, the present inventive concept is not limited thereto. In addition, for example, the gate electrode 130 may include silicon or silicon germanium other than a metal.

The gate electrode 130 is illustrated as being embodied as a single film. However, this is an example. In another example, the gate electrode 130 may be formed by stacking a plurality of conductive material layers. For example, the gate electrode 130 may include a work function adjustment film for adjusting a work function and a filling conductive film filling a space defined by the work function adjustment film. The work function adjustment film may include, for example, at least one of TiN, TaN, TiC, TaC, TiAlC, or combinations thereof. The filling conductive film may include, for example, W or Al. The gate electrode 130 may be formed by, for example, a replacement process. However, the present inventive concept is not limited thereto.

The gate dielectric film 120 may be interposed between the active patterns P1 to P4 and the gate electrode 130. For example, the gate dielectric film 120 may extend along a top face of the field insulating film 105 and a top face and a side face of each of the active patterns P1 to P4.

The gate dielectric film 120 may include, for example, at least one of silicon oxide, silicon oxynitride, silicon nitride, and a high-k material with a higher dielectric constant than that of silicon oxide. The high dielectric constant material may include, for example, at least one of hafnium oxide (HfO₂), zirconium oxide (ZrO₂), lanthanum oxide (La₂O₃), aluminum oxide (Al₂O₃), titanium oxide (TiO₂), strontium titanium oxide (SrTiO₃), lanthanum aluminum oxide (LaAlO₃), yttrium oxide (Y₂O₃), hafnium oxynitride (HfOₓN_{y}), zirconium oxynitride (ZrOₓN_{y}), lanthanum oxynitride (La₂OₓN_{y}), aluminum oxynitride (Al₂OₓN_{y}), titanium oxynitride (TiOₓN_{y}), strontium titanium oxynitride (SrTiOₓN_{y}), lanthanum aluminum oxynitride (LaAlOₓN_{y}), yttrium oxynitride (Y₂OₓN_{y}) or combinations thereof. However, the present inventive concept is not limited thereto.

The gate spacer 140 may extend along a side face of the gate electrode 130. The gate spacer 140 may include, for example, at least one of silicon oxide, silicon nitride, silicon oxynitride, or combinations thereof. However, the present inventive concept is not limited thereto.

In some embodiments of the present inventive concept, a portion of the gate dielectric film 120 may be interposed between the gate electrode 130 and the gate spacer 140. For example, the gate dielectric film 120 may further extend along an inner side face of the gate spacer 140.

The gate capping pattern 150 may extend along a top face of the gate electrode 130. The gate capping pattern 150 may include, for example, at least one of silicon oxide, silicon nitride, silicon oxynitride, or combinations thereof. However, the present inventive concept is not limited thereto.

It is illustrated that a top face of the gate capping pattern 150 is substantially coplanar with a top face of the gate spacer 140. However, this is an example. In another example, the gate capping pattern 150 may cover the top face of the gate spacer 140.

A first source/drain area 161 may be formed on the first active pattern P1 and P2. For example, the first source/drain area 161 may be formed in a portion of the first active pattern P1 and P2 on each of both opposing side faces of the gate structure GS. The first source/drain area 161 may be electrically isolated from the gate electrode 130 via the gate spacer 140.

A second source/drain area 162 may be formed on the second active pattern P3 and P4. For example, the second source/drain area 162 may be formed in a portion of the second active pattern P3 and P4 on each of both opposing side faces of the gate structure GS. The second source/drain area 162 may be electrically isolated from the gate electrode 130 via the gate spacer 140.

In some embodiments of the present inventive concept, the first source/drain area 161 may include an epitaxial layer formed on the first active pattern P1 and P2. The second source/drain area 162 may include epitaxial layers formed on the second active pattern P3 and P4. It is illustrated that the first source/drain area 161 is an epitaxial layer merged with the first sub-pattern P1 and the second sub-pattern P2, while the second source/drain area 162 is an epitaxial layer merged with the third sub-pattern P3 and the fourth sub-pattern P4. However, this is an example. In another example, at least one of the first source/drain area 160 or the second source/drain area 260 may be an unmerged epitaxial layer.

When the first active area AR1 is a PFET area, the first source/drain area 161 may include p-type impurities, or impurities for preventing diffusion of the p-type impurities. For example, the first source/drain area 161 may include at least one of B, C, In, Ga, Al or a combination thereof.

When the second active area AR2 is an NFET area, the second source/drain area 162 may include n-type impurities, or impurities for preventing diffusion of the n-type impurities. For example, the second source/drain area 162 may include at least one of P, Sb, As, or a combination thereof.

Although each of the first source/drain area 161 and the second source/drain area 162 is illustrated as being embodied as a single film, this is only an example. In another example, each of the first source/drain area 161 and the second source/drain area 162 may be formed as a stack of multiple epitaxial layers respectively including impurities at different concentrations.

An example in which each of the first electronic element TR1 and the second electronic element TR2 is embodied as a fin-shaped transistor (FinFET) including a channel area of a fin-shaped pattern has been described. However, this is an example. In another example, each of the first electronic element TR1 and the second electronic element TR2 may be embodied as a tunneling transistor (tunneling FET), a transistor including a nanowire, a transistor including a nanosheet, a VFET (Vertical FET), a CFET (Complementary FET), or a three-dimensional (3D) transistor. In addition, each of the first electronic element TR1 and the second electronic element TR2 may be embodied as a bipolar junction transistor, a lateral double diffusion transistor (LDMOS), or the like.

In some embodiments of the present inventive concept, each of the first electronic element TR1 and the second electronic element TR2 may include an NC (Negative Capacitance) FET using a negative capacitor. For example, the gate dielectric film 120 may include a ferroelectric material film having ferroelectric properties and a paraelectric material film having paraelectric properties.

The ferroelectric material film may have negative capacitance, and the paraelectric material film may have positive capacitance. For example, when two or more capacitors may be connected in series to each other, and capacitance of each of the capacitors has a positive value, a total capacitance is smaller than capacitance of each individual capacitor. In addition, when at least one of capacitances of two or more capacitors connected in series to each other has a negative value, a total capacitance may have a positive value and be greater than an absolute value of each individual capacitance.

When the ferroelectric material film with negative capacitance and the paraelectric material film with positive capacitance are connected in series to each other, a total capacitance value of the ferroelectric material film and the paraelectric material film connected in series to each other may be increased. Using the increase in the total capacitance value, a transistor including the ferroelectric material film may have a subthreshold swing (SS) lower than about 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. In this connection, in one example, hafnium zirconium oxide may refer to a material obtained by doping hafnium oxide with zirconium (Zr). In another example, hafnium zirconium oxide may refer to a compound of hafnium (Hf), zirconium (Zr), and oxygen (O).

The ferroelectric material film may further include doped dopants. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) and/or tin (Sn). A type of the dopant included in the ferroelectric material film may vary depending on a type of the ferroelectric material included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and/or yttrium (Y).

When the dopant is aluminum (Al), the ferroelectric material film may include about 3 to about 8 at % (atomic %) of aluminum. In this connection, a content of the dopant may be a content of aluminum based on a sum of hafnium and aluminum.

When the dopant is silicon (Si), the ferroelectric material film may include about 2 to about 10 at % of silicon. When the dopant is yttrium (Y), the ferroelectric material film may include about 2 to about 10 at % yttrium. When the dopant is gadolinium (Gd), the ferroelectric material film may include about 1 to about 7 at % gadolinium. When the dopant is zirconium (Zr), the ferroelectric material film may include about 50 to about 80 at % zirconium.

The paraelectric material film may have paraelectric properties. The paraelectric material film may include, for example, at least one of silicon oxide and metal oxide having a high dielectric constant. Although the metal oxide included in the paraelectric material film may include, for example, at least one of hafnium oxide, zirconium oxide and aluminum oxide. However, the present inventive concept is not limited thereto.

The ferroelectric material film and the paraelectric material film may include the same material. The ferroelectric material film may have ferroelectric properties, but the paraelectric material film might not have the ferroelectric properties. For example, when each of the ferroelectric material film and the paraelectric material film includes hafnium oxide, a crystal structure of hafnium oxide included in the ferroelectric material film is different from a crystal structure of hafnium oxide included in the paraelectric material film.

The ferroelectric material film may have a thickness sized to exhibit ferroelectric properties. Although the thickness of the ferroelectric material film may be, for example, in a range of about 0.5 to about 10 nm, the present inventive concept is not limited thereto. Because a critical thickness exhibiting the ferroelectric properties may vary based on a type of the ferroelectric material, the thickness of the ferroelectric material film may vary depending on the type of the ferroelectric material.

In one example, the gate insulating film 120 may include one ferroelectric material film. In another example, the gate insulating film 120 may include a plurality of ferroelectric material films spaced apart from each other. The gate insulating film 120 may have a multilayer structure in which a plurality of ferroelectric material films and a plurality of paraelectric material films are alternately stacked on top of each other.

The interlayer insulating films 110 and 210 may cover the first electronic element TR1 and the second electronic element TR2. For example, the interlayer insulating films 110 and 210 may include a first interlayer insulating film 110 and a second interlayer insulating film 210 sequentially stacked on the first face 100a of the substrate 100. The first interlayer insulating film 110 may cover the field insulating film 105, the first source/drain area 160, and the second source/drain area 260. The second interlayer insulating film 210 may cover the gate structure GS and the first interlayer insulating film 110.

Each of the interlayer insulating films 110 and 210 may include, for example, at least one of silicon oxide, silicon oxynitride, and a low-k material with a lower dielectric constant than that of silicon oxide. However, the present inventive concept is not limited thereto.

The front wiring structure FS may be disposed on the first face 100a of the substrate 100. For example, the front wiring structure FS may be formed on the top face of the second interlayer insulating film 210. The front wiring structure FS may provide a signal line and/or a power line for various electronic elements (for example, the first electronic element TR1 and the second electronic element TR2) formed on the first face 100a of the substrate 100.

For example, the front wiring structure FS may include a front inter-wiring insulating film 310, a plurality of front wiring patterns FM1 to FM4, and a plurality of front via patterns FV1 to FV4. The front wiring patterns FM1 to FM4 and the front via patterns FV1 to FV4 may be formed in the front inter-wiring insulating film 310. The front wiring patterns FM1 to FM4 may be insulated from each other via the front inter-wiring insulating film 310. The front via patterns FV1 to FV4 may be insulated from each other via the front inter-wiring insulating film 310. The number of layers, the number, and an arrangement of the front inter-wiring insulating film 310, the front wiring patterns FM1 to FM4, and the front via patterns FV1 to FV4 are only examples, and are not limited to those as shown.

The front wiring patterns FM1 to FM4 may be sequentially stacked on the first face 100a of the substrate 100. The front via patterns FV1 to FV4 may be sequentially stacked on the first face 100a of the substrate 100. Each of the front via patterns FV1 to FV4 may connect vertically adjacent ones of the front wiring patterns FM1 to FM4 to each other.

In some embodiments of the present inventive concept, a width of each of the front via patterns FV1 to FV4 may decrease as each of the front via patterns FV1 to FV4 extends toward the first face 100a of the substrate 100. This may be attributed to characteristics of an etching process for forming each of the front via patterns FV1 to FV4. For example, each of the front via patterns FV1 to FV4 may have a tapered shape.

The front wiring structure FS may be connected to the first electronic element TR1 and the second electronic element TR2. For example, a first source/drain contact CA1 may be formed on the first active area AR1, and a second source/drain contact CA2 may be formed on the second active area AR2. The first source/drain contact CA1 may extend through the interlayer insulating films 110 and 210 and then be connected to the first source/drain area 161. The second source/drain contact CA2 may extend through the interlayer insulating films 110 and 210 and then be connected to the second source/drain area 162. The first front via pattern FV1 of the front wiring structure FS may be connected to the first source/drain contact CA1 and/or the second source/drain contact CA2. Thus, the front wiring structure FS may be electrically connected to the first source/drain area 161 and the second source/drain area 162.

In some embodiments of the present inventive concept, a gate contact CB may be formed on the gate structure GS. The gate contact CB may extend through the interlayer insulating films 110 and 210 and the gate capping pattern 150 and then be connected to the gate electrode 130. The gate contact CB may connect the gate electrode 130 and the first front wiring pattern FM1 to each other. Thus, the front wiring structure FS may be electrically connected to the gate electrode 130. In some embodiments of the present inventive concept, the gate contact CB may connect the gate electrode 130 and the first front via pattern FV1 to each other.

In some embodiments of the present inventive concept, a width of each of the first source/drain contact CA1, the second source/drain contact CA2, and the gate contact CB may decrease as each of the first source/drain contact CA1, the second source/drain contact CA2, and the gate contact CB extends toward the first face 100a of the substrate 100. For example, each of the first source/drain contact CA1, the second source/drain contact CA2, and the gate contact CB may have a tapered shape. This may be due to characteristics of an etching process for forming each of the first source/drain contact CA1, the second source/drain contact CA2, and the gate contact CB.

For example, each of the front wiring patterns FM1 to FM4 and the front via patterns FV1 to FV4 may include a barrier conductive film and a filling conductive film. The barrier conductive film may include a metal or metal nitride for preventing diffusion of the filling conductive film. The barrier conductive film may include, for example, at least one of titanium (Ti), tantalum (Ta), tungsten (W), nickel (Ni), cobalt (Co), platinum (Pt), alloys thereof, or nitrides thereof. However, the present inventive concept is not limited thereto. The filling conductive film may include, for example, at least one of aluminum (Al), copper (Cu), tungsten (W), molybdenum (Mo), cobalt (Co), ruthenium (Ru), and alloys thereof. However, the present inventive concept is not limited thereto.

The trench capacitor TC may be disposed on the second face 100b of the substrate 100. Further, at least a portion of the trench capacitor TC may be disposed in the substrate 100. For example, a back trench 100t3 extending from the second face 100b of the substrate 100 may be formed in the substrate 100. The trench capacitor TC may fill at least a portion of the back trench 100t3. The back trench 100t3 may be a deep trench formed in the substrate 100. The number and an arrangement of trench capacitors TC are merely examples, and are not limited to those as shown.

In some embodiments of the present inventive concept, a depth (DT in FIG. 3A) of the back trench 100t3 may be about 50% or greater of a thickness (TH in FIG. 2) of the substrate 100. For example, the depth DT of the back trench 100t3 may be about 50% to about 95% of the thickness TH of the substrate 100.

In some embodiments of the present inventive concept, the thickness TH of the substrate 100 may be in a range of about 150 nm to about 700 nm. The substrate 100 may be provided using a thinning process. However, the present inventive concept is not limited thereto.

The trench capacitor TC may include a first electrode film 192, a capacitor dielectric film 194, and a second electrode film 196 sequentially stacked on the substrate 100. The first electrode film 192 and the second electrode film 196 may face each other. The capacitor dielectric film 194 may be interposed between the first electrode film 192 and the second electrode film 196. The trench capacitor TC may store charges in the capacitor dielectric film 194 using a potential difference generated between the first electrode film 192 and the second electrode film 196.

For example, the first electrode film 192 may conformally extend along a profile of the back trench 100t3. A portion of the first electrode film 192 may further extend along the second face 100b of the substrate 100. The capacitor dielectric film 194 may conformally extend along at least a portion of a profile of the first electrode film 192. The second electrode film 196 may be formed on the capacitor dielectric film 194. In some embodiments of the present inventive concept, the second electrode film 196 may fill an area of the back trench 100t3 remaining after the first electrode film 192 and the capacitor dielectric film 194 have filled a portion of the back trench 100t3. In some embodiments of the present inventive concept, the second electrode film 196 might not entirely fill the back trench 100t3. In one example, the second electrode film 196 may conformally extend along at least a portion of the profile of the capacitor dielectric film 194.

Each of the first electrode film 192 and the second electrode film 196 may include a conductive material such as a metal, a metal nitride, or a doped semiconductor material such as doped polysilicon. However, the present inventive concept is not limited thereto. The capacitor dielectric film 194 may include, for example, at least one of silicon oxide, silicon oxynitride, silicon nitride, and a high-k material with a higher dielectric constant than that of silicon oxide. However, the present inventive concept is not limited thereto.

In some embodiments of the present inventive concept, as shown in FIG. 3A, the trench capacitor TC may further include an isolation insulating film 191 and a capacitor spacer 198.

The isolation insulating film 191 may be interposed between the substrate 100 and the first electrode film 192. For example, the isolation insulating film 191 may conformally extend along the profile of the back trench 100t3 and along the second face 100b of the substrate 100. The first electrode film 192 may be stacked on the isolation insulating film 191. In some embodiments of the present inventive concept, the first electrode film 192 may be electrically isolated from the substrate 100 via the isolation insulating film 191. The isolation insulating film 191 may include, for example, at least one of silicon oxide, silicon nitride, silicon oxynitride, silicon oxycarbonitride, or a combination thereof. However, the present inventive concept is not limited thereto.

The capacitor spacer 198 may be formed on a side face of the capacitor dielectric film 194 and/or a side face of the second electrode film 196. In some embodiments of the present inventive concept, the capacitor spacer198 may be formed on a side face of the first electrode film 192. The capacitor spacer 198 may prevent a short circuit between the side face of the first electrode film 192 and the side face of the second electrode film 196. The capacitor spacer 198 may include an insulating material, for example, at least one of silicon oxide, silicon nitride, silicon oxynitride, silicon oxycarbonitride, or a combination thereof. However, the present inventive concept is not limited thereto.

In some embodiments of the present inventive concept, as shown in FIG. 3B, the trench capacitor TC may include an impurity area in the substrate 100.

For example, the first electrode film 192 may be an impurity area formed by doping impurities in an area of the substrate 100 including the back trench 100t3. In one example, the first electrode film 192 may be a p-type impurity area doped with a p-type impurity, such as B, C, In, Ga, or Al. In another example, the first electrode film 192 may be an n-type impurity area doped with an n-type impurity, such as P, Sb, or As.

In some embodiments of the present inventive concept, the back trench 100t3 may define a plurality of isolated areas in the substrate 100. In one example, as shown in FIG. 6A, each of the back trenches 100t3 may have a pillar shape, for example, a circular pillar shape or cylindrical shape. It is illustrated only that the pillar-shaped back trenches 100t3 are arranged in a lattice form in a plan view (for example, an XY plane). However, this is an example. In another example, the pillar-shaped back trenches 100t3 may be arranged in various other forms such as a zigzag form, a honeycomb form, and an alternating arrangement.

In another example, as shown in FIG. 6B, each back trench 100t3 may extend in an elongated manner in the first direction X. The back trench 100t3 may extend in parallel with each of the active patterns P1 to P4. In another example, as shown in FIG. 6C, each of the back trenches 100t3 may extend in an elongated manner in the second direction Y. The back trenches 100t3 may extend in parallel to the gate structure GS.

However, these are only examples, and the shape of the back trench 100t3 is not limited to the illustrated one. As long as the first electrode film 192, the capacitor dielectric film 194, and the second electrode film 196 are sequentially stacked in the back trench 100t3, the back trench 100t3 may have various shapes.

The back wiring structure BS may be disposed on the second face 100b of the substrate 100. The back wiring structure BS may provide a signal line and/or a power line for various electronic elements (for example, the first electronic element TR1 and the second electronic element TR2) formed on the first face 100a of the substrate 100.

For example, the back wiring structure BS may include a back inter-wiring insulating film 320, a plurality of back wiring patterns BM1 to BM3, and a plurality of back via patterns BV1 to BV3. The back wiring patterns BM1 to BM3 and the back via patterns BV1 to BV3 may be formed in the back inter-wiring insulating film 320. The back wiring patterns BM1 to BM3 may be insulated from each other via the back inter-wiring insulating film 320. The back via patterns BV1 to BV3 may be insulated from each other via the back inter-wiring insulating film 320. The number of layers, the number, and an arrangement of the back inter-wiring insulating film 320, the back wiring patterns BM1 to BM3, and the back via patterns BV1 to BV3 are examples, and are not limited thereto.

The back wiring patterns BM 1 to BM3 may be sequentially stacked on the second face 100b of the substrate 100. The back via patterns BV1 to BV3 may be sequentially stacked on the second face 100b of the substrate 100. Each of the back via patterns BV1 to BV3 may connect vertically adjacent ones of the back wiring patterns BM1 to BM3 to each other.

In some embodiments of the present inventive concept, a width of each of the back via patterns BV1 to BV3 may decrease as each of the back via patterns BV1 to BV3 extends toward the second face 100b of the substrate 100. For example, each of the back via patterns BV1 to BV3 may have a tapered shape. This may be attributed to the characteristics of an etching process for forming each of the back via patterns BV1 to BV3.

Each of the back wiring patterns BM1 to BM3 and the back via patterns BV1 to BV3 may include a barrier conductive film and a filling conductive film. The barrier conductive film may include a metal or metal nitride for preventing diffusion of the filling conductive film. The barrier conductive film may include, for example, at least one of titanium (Ti), tantalum (Ta), tungsten (W), nickel (Ni), cobalt (Co), platinum (Pt), alloys thereof, or nitrides thereof. However, the present inventive concept is not limited thereto. The filling conductive film may include, for example, at least one of aluminum (Al), copper (Cu), tungsten (W), molybdenum (Mo), cobalt (Co), ruthenium (Ru), and alloys thereof. However, the present inventive concept is not limited thereto.

Each of the first through-via TV1 and the second through-via TV2 may extend through the substrate 100. For example, the first through-via TV1 and the second through-via TV2 may extend in the third direction Z intersecting the first direction X and the second direction Y to extend through the substrate 100.

The first through-via TV1 may electrically connect the first electronic element TR1 and the back wiring structure BS to each other. In some embodiments of the present inventive concept, the first through-via TV1 may connect the bottommost pattern (e.g., the first back via pattern BV1 or the first back wiring pattern BM1) of the back wiring structure BS and the first source/drain contact CA1 to each other. It is illustrated only that the topmost face of the first through-via TV1 is in contact with the bottommost face of the first source/drain contact CA1. However, this is an example. In another example, the topmost face of the first through-via TV1 may be formed at a higher level than a level of the bottommost face of the first source/drain contact CA1.

The second through-via TV2 may electrically connect the second electronic element TR2 and the back wiring structure BS to each other. In some embodiments of the present inventive concept, the second through-via TV2 may connect the bottommost pattern (for example, the first back via pattern BV1 or the first back wiring pattern BM1) of the back wiring structure BS and the second source/drain contact CA2 to each other. It is illustrated that the topmost face of the second through-via TV2 contacts the bottommost face of the second source/drain contact CA2. However, this is only an example. In another example, the topmost face of the second through-via TV2 may be formed at a higher level than a level of the bottommost face of the second source/drain contact CA2.

In some embodiments of the present inventive concept, each of the first through-via TV1 and the second through-via TV2 may include a through-conductive film 292 and a through-spacer 294. The through-spacer 294 may surround a side face of the through-conductive film 292. The through-conductive film 292 may include, for example, at least one of aluminum (Al), copper (Cu), tungsten (W), molybdenum (Mo), cobalt (Co), ruthenium (Ru), or alloys thereof. However, the present inventive concept is not limited thereto. The through-spacer 294 may include an insulating material for electrically isolating the through-conductive film 292 from the substrate 100. For example, the through-spacer 294 may include at least one of silicon oxide, silicon nitride, silicon oxynitride, silicon oxycarbonitride, or a combination thereof. However, the present inventive concept is not limited thereto.

In some embodiments of the present inventive concept, a width of each of the first through-via TV1 and the second through-via TV2 may gradually decrease as each of the first through-via TV1 and the second through-via TV2 extends in a direction from the front wiring structure FS to the back wiring structure BS (for example, in a −Z direction). For example, each of the first through-via TV1 and the second through-via TV2 may have a tapered shape. This may be due to a fact that an etching process for forming the first through-via TV1 and the second through-via TV2 is performed on the first face 100a of the substrate 100.

In some embodiments of the present inventive concept, a width WD of each of the first through-via TV1 and the second through-via TV2 may be smaller than or equal to about 100 nm. For example, the width WD of each of the first through-via TV1 and the second through-via TV2 may be in a range of about 10 nm to about 100 nm. Each of the first through-via TV1 and the second through-via TV2 may have a relatively small critical dimension (CD) such that integration of the semiconductor device may be increased.

In some embodiments of the present inventive concept, the back wiring structure BS includes a power delivery network (PDN) for the first electronic element TR1 and/or the second electronic element TR2. For example, a power voltage such as a source voltage V_{SS} or a drain voltage V_{DD} supplied from an external source may be provided to the topmost wiring (for example, the third back wiring pattern BM3) of the back wiring structure BS and then may be applied to the first electronic element TR1 and/or the second electronic element TR2 via the back wiring structure BS. In one example, a first power voltage (e.g., the drain voltage V_{DD}) may be provided to the first electronic element TR1 via the back wiring structure BS and the first through-via TV1. In one example, a second power voltage (e.g., the source voltage V_{SS}) different from the first power voltage may be provided to the second electronic element TR2 via the back wiring structure BS and the second through-via TV2.

In some embodiments of the present inventive concept, the back wiring structure BS may be connected with the trench capacitor TC. For example, as shown in FIG. 3A and FIG. 3B, the back wiring structure BS may include a first connection via BV11 and a second connection via BV12. The first connection via BV11 may be connected to the second electrode film 196, while the second connection via BV12 may be connected to the first electrode film 192. Each of the first connection via BV11 and the second connection via BV12 may be the bottommost pattern (for example, the first back via pattern BV1) of the back wiring structure BS. However, the present inventive concept is not limited thereto.

In some embodiments of the present inventive concept, the power voltage such as the source voltage V_{SS} or the drain voltage V_{DD} may be applied to the first electrode film 192 and/or the second electrode film 196 via the back wiring structure BS. In one example, the first power voltage (e.g., the drain voltage V_{DD}) may be provided to the first electrode film 192 via the second connection via BV12. In one example, the second power voltage (e.g., the source voltage V_{SS}) may be provided to the second electrode film 196 via the first connection via BV11.

In some embodiments of the present inventive concept, the back wiring structure BS may electrically connect the trench capacitor TC and the first through-via TV1 and/or the second through-via TV2 to each other. In one example, the back wiring structure BS may electrically connect the first electrode film 192 and the second through-via TV2 to each other. In one example, the back wiring structure BS may electrically connect the second electrode film 196 and the first through-via TV1 to each other. Thus, the trench capacitor TC may act as a capacitor of the power delivery network (PDN) for the first electronic element TR1 and/or the second electronic element TR2.

As the semiconductor device becomes increasingly integrated, a width of each of the wiring patterns and the via patterns that constitute the semiconductor device is gradually decreasing. Due to this decrease, voltage drop (for example, IR drop) of the power delivery network (PDN) that supplies the power voltage to the electronic elements may develop.

In a semiconductor device according to some embodiments of the present inventive concept, the power supply network (PDN) may have a reduced voltage drop. For example, as described above, the back wiring structure BS providing the power supply network (PDN) may be disposed on the back face (for example, the second face 100b) of the substrate 100. Thus, the front wiring structure FS of the semiconductor device according to some embodiments of the present inventive concept may be formed to be relatively large, compared to a case where the power supply network (PDN) is disposed on the front face (for example, the first face 100a) of the substrate 100.

Further, the semiconductor device according to some embodiments of the present inventive concept may have increased power performance using the trench capacitor TC. For example, as described above, the trench capacitor TC may be formed to fill the deep trench (for example, the back trench 100t3) formed in the substrate 100 and thus may have relatively high performance (high capacitance and low resistance) compared to a MIM capacitor (Metal-Insulator-Metal capacitor) which is formed in a planar manner. Further, this high-performance trench capacitor TC may act as the capacitor of the power delivery network (PDN), thereby minimizing power supply noise, and may function as a temporary current source for applying high frequency current. Thus, the semiconductor device with increased PPAC (Power, Performance, Area, and Cost) may be provided.

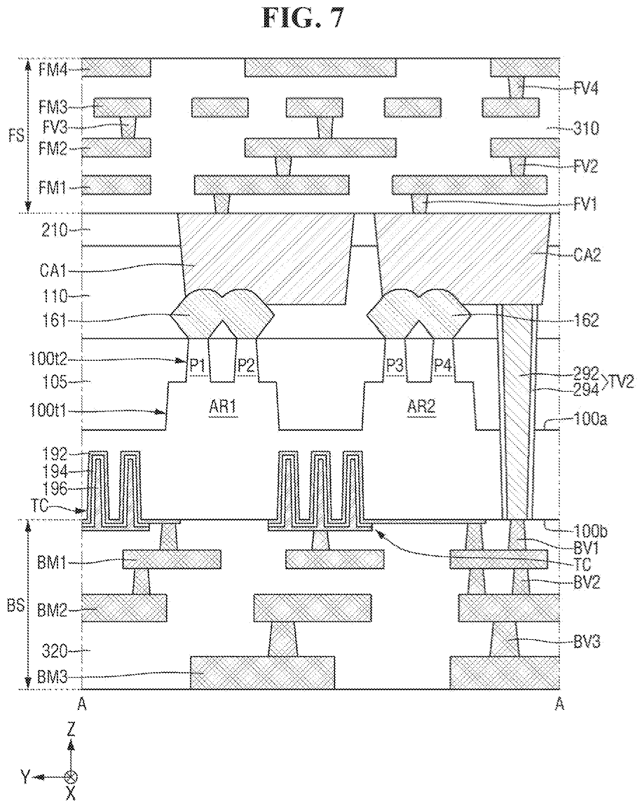

FIG. 7 is a schematic cross-sectional view for illustrating a semiconductor device according to an embodiment of the present inventive concept. For convenience of description, descriptions that are redundant with the descriptions as set forth above using FIG. 1 to FIG. 6C may be briefly set forth or omitted. For reference, FIG. 7 is another schematic cross-sectional view taken along A-A of FIG. 1.

Referring to FIG. 7, in the semiconductor device according to an embodiment of the present inventive concept, at least a portion of the trench capacitor TC might not overlap the active patterns P1 to P4.

For example, the trench capacitor TC may be formed in an area of the substrate 100 in which the first active area AR1 and the second active area AR2 are not formed. In one example, as shown, the trench capacitor TC may be disposed under a portion of the field insulating film 105 filling the first element isolation trench 100t1. For example, the trench capacitor may overlap the first element isolation trench 100t. It is illustrated that the trench capacitor TC is disposed on each of both sides of the first active area AR1. However, this is only an example, and the trench capacitor TC may be disposed on one side of the first active area AR1.

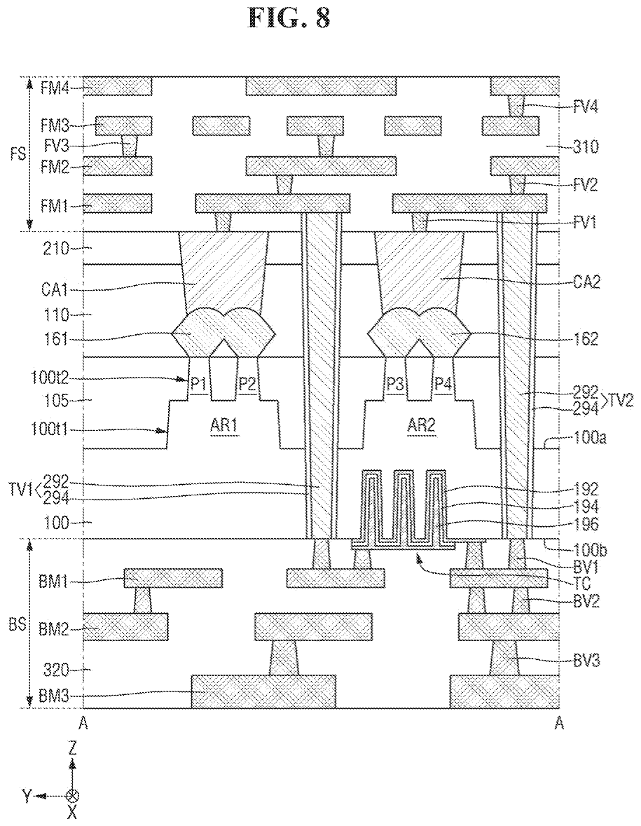

FIG. 8 is a schematic cross-sectional view for illustrating a semiconductor device according to an embodiment of the present inventive concept. For convenience of description, descriptions that are redundant with the descriptions as set forth above using FIG. 1 to FIG. 7 may be briefly set forth or omitted. For reference, FIG. 8 is another schematic cross-sectional view taken along A-A of FIG. 1.

Referring to FIG. 8, in the semiconductor device according to an embodiment of the present inventive concept, the first through-via TV1 and/or the second through-via TV2 may be connected to the front wiring structure FS.

For example, each of the first through-via TV1 and/or the second through-via TV2 may be connected to the bottommost pattern (for example, the first front via pattern FV1 or the first front wiring pattern FM1) of the front wiring structure FS. Thus, each of the first through-via TV1 and/or the second through-via TV2 may connect the front wiring structure FS and the back wiring structure BS to each other. Further, the trench capacitor TC may be connected to the first electronic element TR1 and/or the second electronic element TR2.

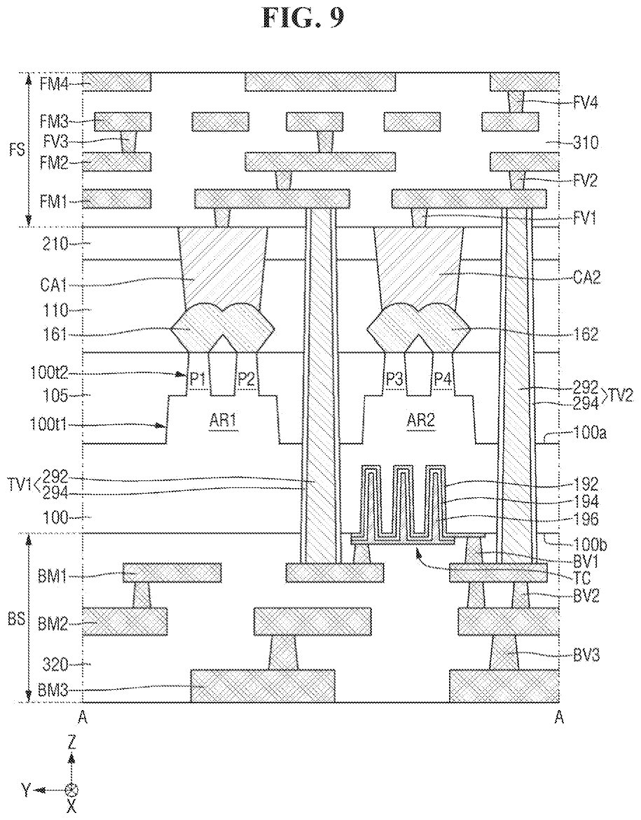

FIG. 9 is a schematic cross-sectional view for illustrating a semiconductor device according to an embodiment of the present inventive concept. For convenience of description, descriptions that are redundant with the descriptions as set forth above using FIG. 1 to FIG. 8 may be briefly set forth or omitted. For reference, FIG. 9 is another schematic cross-sectional view taken along A-A of FIG. 1.

Referring to FIG. 9, in the semiconductor device according to an embodiment of the present inventive concept, a width of each of the first through-via TV1 and the second through-via TV2 may gradually decrease as each of the first through-via TV1 and the second through-via TV2 extends in a direction from the back wiring structure BS to the front wiring structure FS (for example, in the Z direction). This may be attributed to a fact that an etching process for forming the first through-via TV1 and the second through-via TV2 is performed on the second face 100b of the substrate 100.

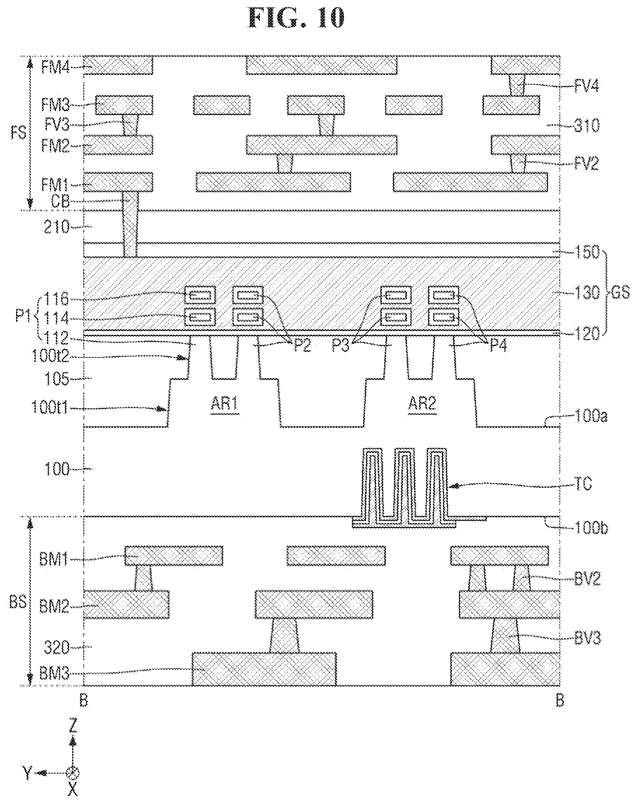

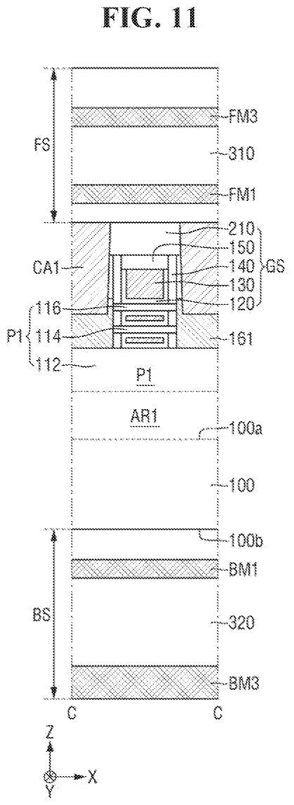

FIG. 10 and FIG. 11 are schematic cross-sectional views for illustrating a semiconductor device according to some embodiments of the present inventive concept. For convenience of description, those duplicate with the descriptions as set forth above using FIG. 1 to FIG. 9 may be briefly set forth or omitted. For reference, FIG. 10 is another schematic cross-sectional view taken along B-B of FIG. 1, and FIG. 11 is another schematic cross-sectional view taken along C-C of FIG. 1.

Referring to FIG. 10 and FIG. 11, in the semiconductor device according to some embodiments of the present inventive concept, each of the active patterns P1 to P4 includes a plurality of bridge patterns 114 and 116.

For example, each of the active patterns P1 to P4 may include first and second bridge patterns 114 and 116 which are sequentially stacked on the first face 100a of the substrate 100 and are spaced apart from each other. Illustratively, the first bridge pattern 114 may be spaced apart from the substrate 100 in the third direction Z, while the second bridge pattern 116 may be spaced apart from the first bridge pattern 114 in the third direction Z. Each of the first and second bridge patterns 114 and 116 may extend in the first direction X and may extend through the gate structure GS. For example, the gate structure GS may surround each of the first and second bridge patterns 114 and 116. The bridge patterns 114 and 116 may be used as a channel area of MBCFET® including a multi-bridge channel. The number of bridge patterns 114 and 116 is only an example, and the present inventive concept is not limited thereto.

In FIG. 10, it is illustrated only that a cross-sectional shape of each of the first and second bridge patterns 114 and 116 is rectangular. However, this is an example. In another example, the cross-sectional shape of each of the first and second bridge patterns 114 and 116 may be circular or other polygonal shapes.

In some embodiments of the present inventive concept, each of the active patterns P1 to P4 may further include a fin pattern 112. The fin pattern 112 may protrude from the first face 100a of the substrate 100 and extend in the first direction X. The first bridge pattern 114 may be spaced apart from the fin pattern 112 in the third direction Z.

Hereinafter, referring to FIG. 1 to FIG. 26, a method for manufacturing a semiconductor device according to an embodiment of the present inventive concept is described.

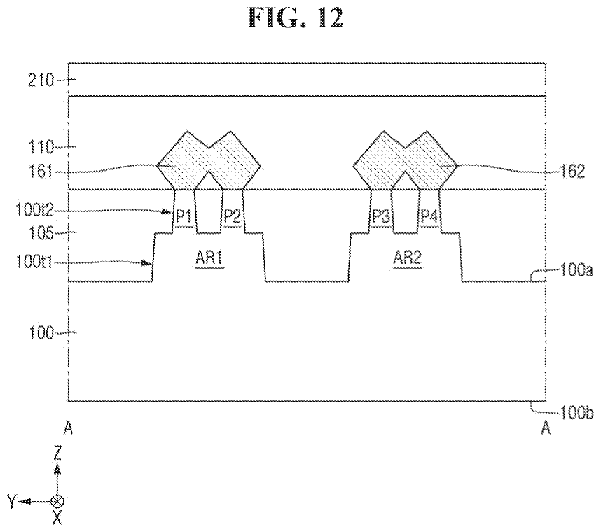

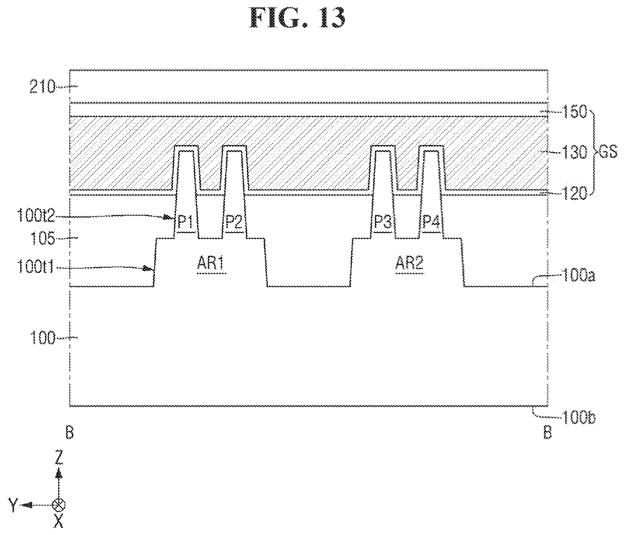

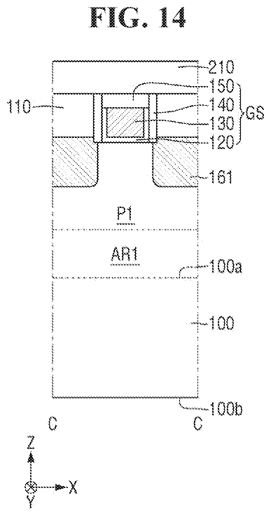

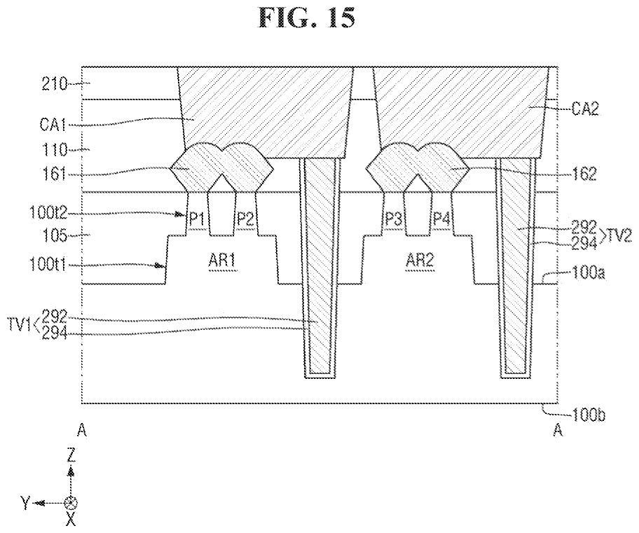

FIG. 12 to FIG. 20 are diagrams of intermediate structures corresponding to intermediate steps for illustrating a method for manufacturing a semiconductor device according to an embodiment of the present inventive concept. For convenience of description, descriptions that are redundant with the descriptions as set forth above using FIG. 1 to FIG. 11 may be briefly set forth or omitted. For reference, FIG. 12 is a cross-sectional view taken along A-A of FIG. 1, and FIG. 13 is a cross-sectional view taken along B-B of FIG. 1. In addition, FIG. 14 is a cross-sectional view taken along C-C of FIG. 1. Further, FIG. 15 to FIG. 20 are cross-sectional views along A-A of FIG. 1.

Referring to FIG. 12 to FIG. 14, electronic elements (TR1 and TR2 of FIG. 1) are formed on the first face 100a of the substrate 100.

For example, the first element isolation trench 100t1 defining the first active area AR1 and the second active area AR2 may be formed in the substrate 100. Further, the second element isolation trench 100t2 defining the active patterns P1 to P4 may be formed. Subsequently, the field insulating film 105 at least partially surrounding at least a portion of the side face of each of the active patterns P1 to P4 may be formed. Subsequently, the gate structure GS, the first source/drain area 161 and the second source/drain area 162 may be formed on the active patterns P1 to P4 and the field insulating film 105.

Subsequently, the interlayer insulating films 110 and 210 covering the electronic elements (TR1 of FIG. 1 and TR2 of FIG. 1) may be formed. For example, the first interlayer insulating film 110 may be formed to cover the field insulating film 105, the first source/drain area 160, and the second source/drain area 260. Then, the second interlayer insulating film 210 covering the gate structure GS and the first interlayer insulating film 110 may be formed.

Referring to FIG. 15, the first through-via TV1, the second through-via TV2, the first source/drain contact CA1, and the second source/drain contact CA2 are formed.

For example, an etching process may be performed on the first face 100a of the substrate 100. In this way, via holes extending in the third direction Z and sequentially extending through the interlayer insulating films 110 and 210, the field insulating film 105, and the first face 100a of the substrate 100 may be formed. The first through-via TV1 and the second through-via TV2 may respectively fill the via holes. For example, the through-spacer 294 and the through-conductive film 292 sequentially stacked in each of the via holes may be formed.

Subsequently, the first source/drain contact CA1 extending through the interlayer insulating films 110 and 210 to be connected to the first through-via TV1 may be formed. Further, the second source/drain contact CA2 extending through the interlayer insulating films 110 and 210 to be connected to the second through-via TV2 may be formed.

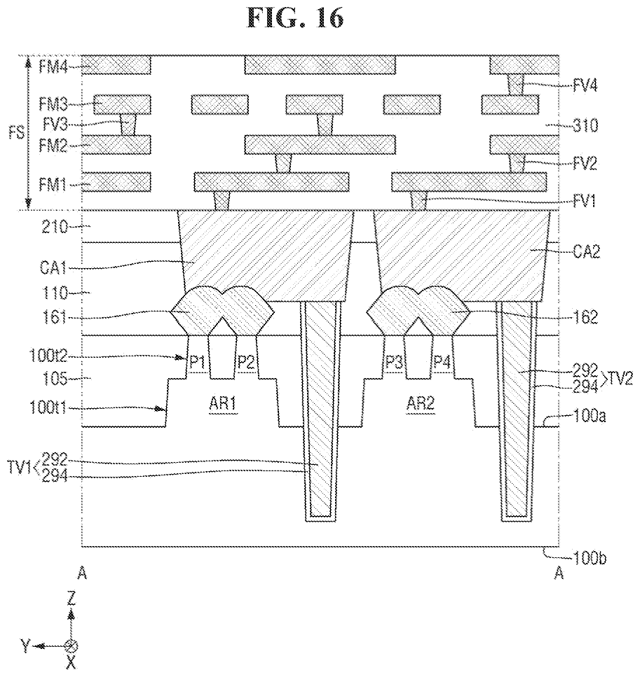

Referring to FIG. 16, the front wiring structure FS is formed on the interlayer insulating films 110 and 210.

For example, the front inter-wiring insulating film 310, the plurality of front wiring patterns FM1 to FM4, and the plurality of front via patterns FV1 to FV4 may be formed on the interlayer insulating films 110 and 210. The front wiring structure FS may provide the signal line and/or the power line for various electronic elements (for example, the first electronic element TR1 and the second electronic element TR2) that are formed on the first face 100a of the substrate 100.

The front wiring structure FS may be connected to the first electronic element TR1 and the second electronic element TR2. For example, the first front via pattern FV1 may be connected to the first source/drain contact CA1 and/or the second source/drain contact CA2.

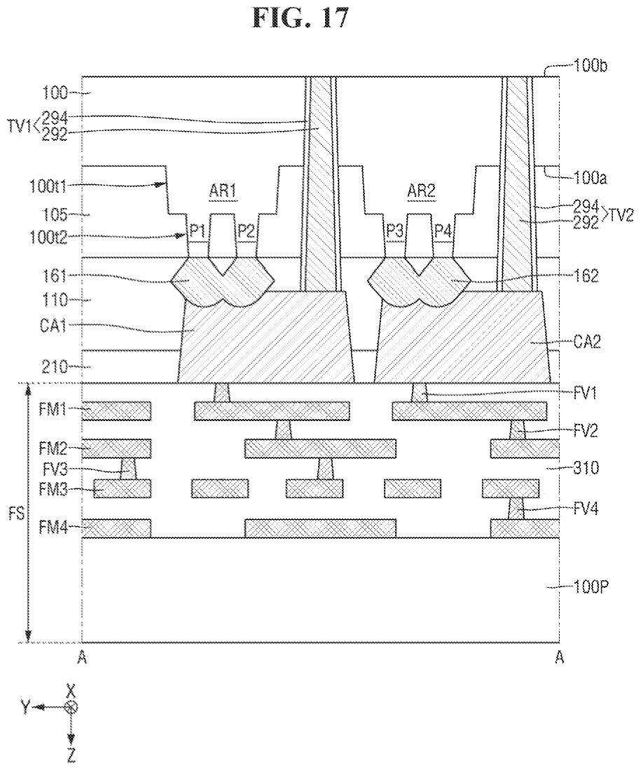

Referring to FIG. 17, the thinning process is performed on the second face 100b of the substrate 100.

For example, a carrier substrate 100P may be attached on the front wiring structure FS. The carrier substrate 100P may function as a support substrate supporting the semiconductor device attached thereto in a subsequent process. After the carrier substrate 100P is attached thereto, the substrate 100 may be turned upside down so that the second face 100b thereof faces upwardly.

Subsequently, the thinning process may be performed. For example, a back grinding process on the second face 100b of the substrate 100 may be performed. Thus, the thickness of the substrate 100 may be reduced such that the substrate 100 may be thinned. In some embodiments of the present inventive concept, the thickness TH of the substrate 100 may be in a range from about 150 nm to about 700 nm.

In some embodiments of the present inventive concept, as the thinning process is performed on the second face 100b of the substrate 100, the first through-via TV1 and the second through-via TV2 might not be covered with the second face 100b of the substrate 100 and may be exposed.

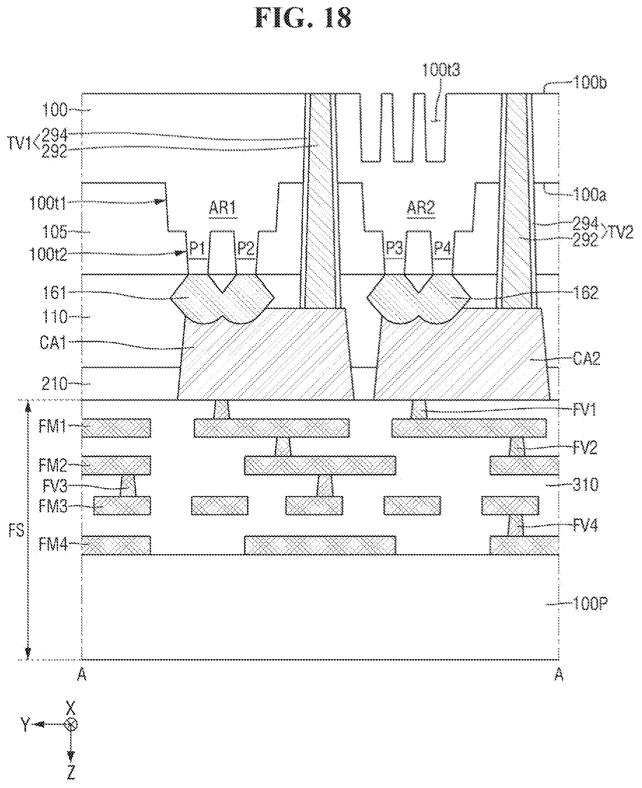

Referring to FIG. 18, the back trench 100t3 is formed in the substrate 100.

For example, an etching process may be performed on the second face 100b of the substrate 100. Thus, the back trench 100t3 extending from the second face 100b of the substrate 100 may be formed.

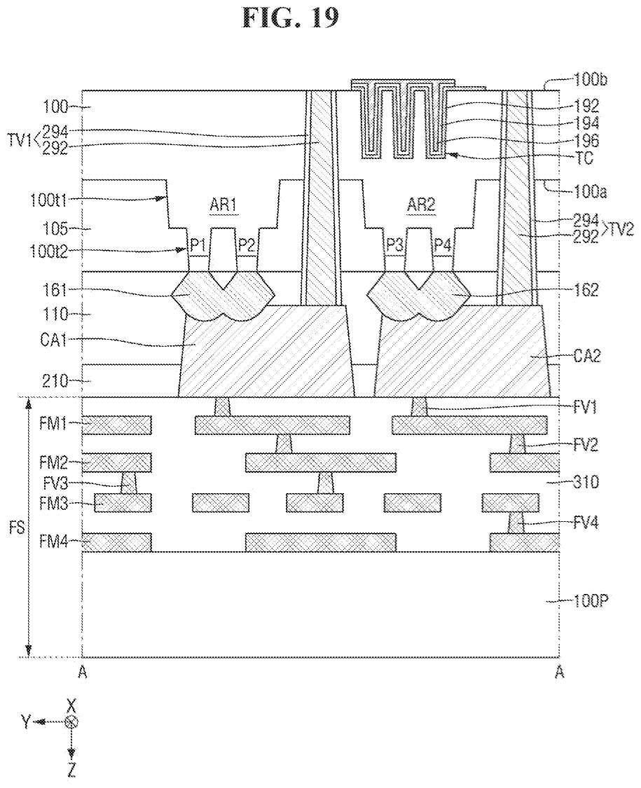

Referring to FIG. 19, the trench capacitor TC filling at least a portion of the back trench 100t3 of FIG. 18 is formed.

The trench capacitor TC may include the first electrode film 192, the capacitor dielectric film 194, and the second electrode film 196 sequentially stacked on the substrate 100. For example, the first electrode film 192, the capacitor dielectric film 194, and the second electrode film 196 may be sequentially stacked in the back trench 100t3 of FIG. 18.

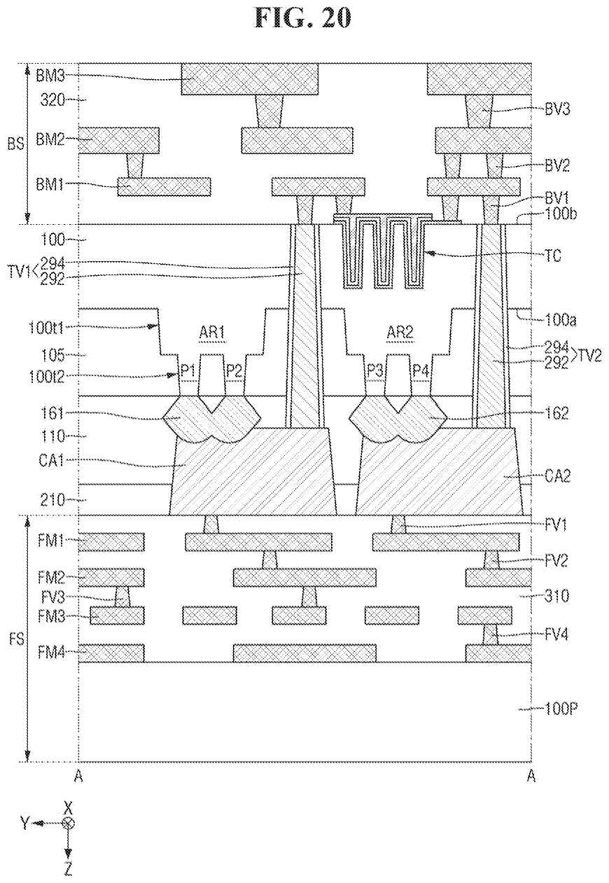

Referring to FIG. 20, the back wiring structure BS is formed on the second face 100b of the substrate 100.

For example, the back inter-wiring insulating film 320, the plurality of back wiring patterns BM1 to BM3, and the plurality of back via patterns BV1 to BV3 may be formed on the second face 100b of the substrate 100. The back wiring structure BS may be electrically connected to the first through-via TV1 and the second through-via TV2. For example, the bottommost pattern (for example, the first back via pattern BV1 or the first back wiring pattern BM1) of the back wiring structure BS may be connected to the first through-via TV1 and/or the second through-via TV2. Thus, the back wiring structure BS may be electrically connected to the first electronic element TR1 and/or the second electronic element TR2. In some embodiments of the present inventive concept, the back wiring structure BS may provide the PDN (Power Delivery Network) for the first electronic element TR1 and/or the second electronic element TR2.

In some embodiments of the present inventive concept, the back wiring structure BS may be connected with the trench capacitor TC. For example, the bottommost pattern (for example, the first back via pattern BV1 or the first back wiring pattern BM1) of the back wiring structure BS may be connected to the first electrode film 192 and/or the second electrode film 196. Thus, the back wiring structure BS may be electrically connected to the trench capacitor TC. In some embodiments of the present inventive concept, the trench capacitor TC may act as the capacitor of the power delivery network (PDN) realized by the back wiring structure BS.

The carrier substrate 100P may then be removed. After the carrier substrate 100P is removed, the substrate 100 may be turned upside down so that the first face 100a faces upwardly. Thus, the semiconductor device as described above using FIG. 1 to FIG. 6C may be manufactured.

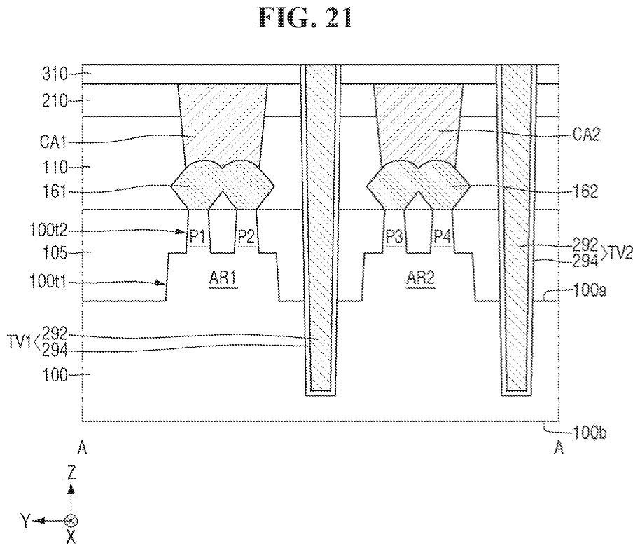

FIG. 21 is a diagram of an intermediate structure corresponding to an intermediate step for illustrating a method for manufacturing a semiconductor device according to an embodiment of the present inventive concept. For convenience of description, descriptions that are redundant with the descriptions as set forth above using FIG. 1 to FIG. 20 may be briefly set forth or omitted. For reference, FIG. 21 is a diagram of an intermediate structure corresponding to an intermediate step after FIG. 12 to FIG. 14.

Referring to FIG. 21, the first source/drain contact CA1 and the second source/drain contact CA2 are formed, and then, the first through-via TV1 and the second through-via TV2 are formed.

For example, the first source/drain contact CA1 extending through the interlayer insulating films 110 and 210 to be connected to the first through-via TV1 may be formed. Further, the second source/drain contact CA2 extending through the interlayer insulating films 110 and 210 to be connected to the second through-via TV2 may be formed. Then, the front inter-wiring insulating film 310 covering the interlayer insulating films 110 and 210, the first source/drain contact CA1 and the second source/drain contact CA2 may be formed.

Subsequently, an etching process may be performed on the first face 100a of the substrate 100. Thus, via holes extending in the third direction Z and extending through the front inter-wiring insulating film 310, the interlayer insulating films 110 and 210, the field insulating film 105, and the first face 100a of the substrate 100 may be formed. The first through-via TV1 and the second through-via TV2 may respectively fill the via holes. For example, the through-spacer 294 and the through-conductive film 292, which are sequentially stacked in each of the via holes, may be formed.

Subsequently, the steps as described above using FIG. 16 to FIG. 20 may be performed. The carrier substrate 100P may then be removed. In this way, the semiconductor device as described above using FIG. 8 may be manufactured.

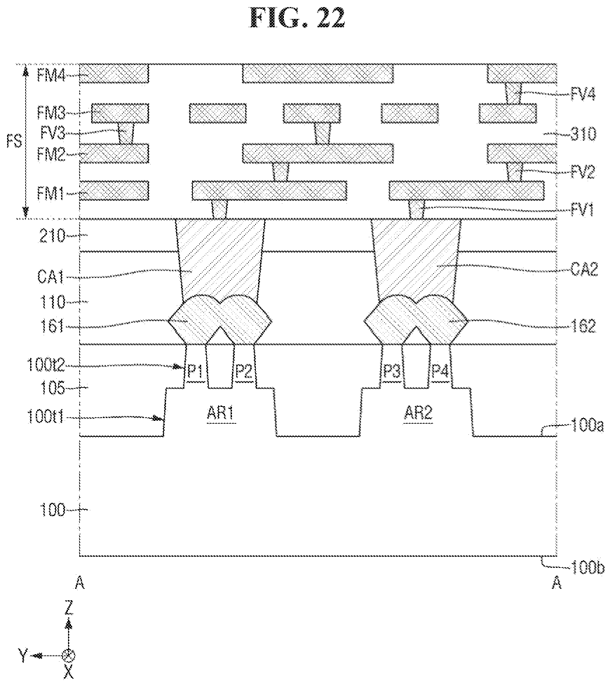

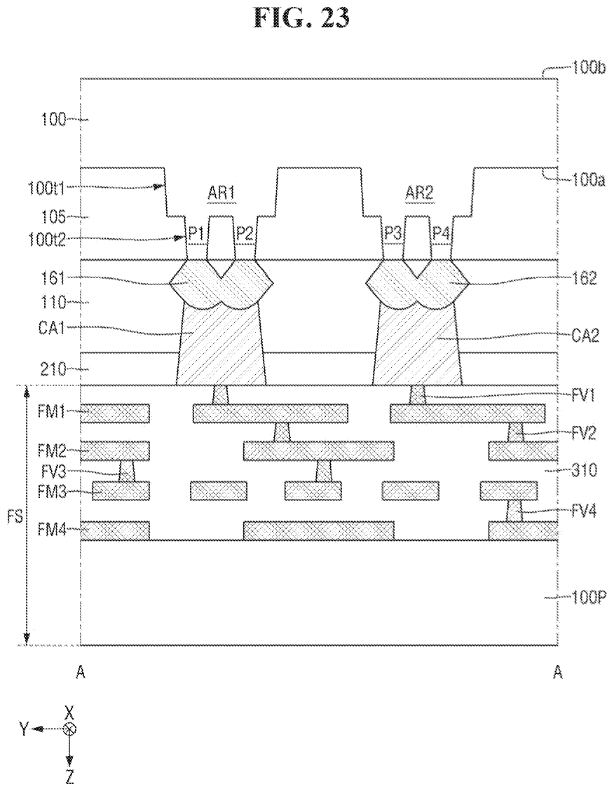

FIG. 22 to FIG. 26 are diagrams of intermediate structures corresponding to intermediate steps for illustrating a method for manufacturing a semiconductor device according to an embodiment of the present inventive concept. For convenience of description, descriptions that are redundant with the descriptions as set forth above using FIG. 1 to FIG. 20 may be briefly set forth or omitted. For reference, FIG. 22 is a diagram of an intermediate structure corresponding to an intermediate step after FIG. 12 to FIG. 14.

Referring to FIG. 22, the first source/drain contact CA1, the second source/drain contact CA2 and the front wiring structure FS are formed.

For example, the first source/drain contact CA1 extending through the interlayer insulating films 110 and 210 to be connected to the first through-via TV1 may be formed. Further, the second source/drain contact CA2 extending through the interlayer insulating films 110 and 210 to be connected to the second through-via TV2 may be formed.

Subsequently, the front wiring structure FS may be formed on the interlayer insulating films 110 and 210. Forming the front wiring structure FS is similar to that as described above using FIG. 16. Thus, a detailed description thereof is omitted below.

Referring to FIG. 23, the carrier substrate 100P is attached on the front wiring structure FS, and the thinning process is performed on the second face 100b of the substrate 100. Performing the thinning process is similar to that as described above using FIG. 17. Thus, a detailed description thereof is omitted below.

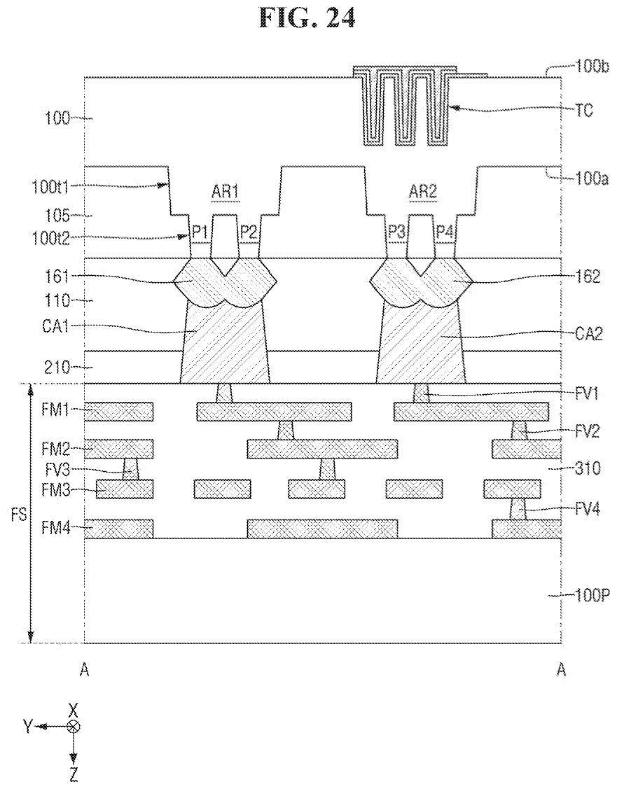

Referring to FIG. 24, the trench capacitor TC is formed on the second face 100b of the substrate 100. Forming the trench capacitor TC is similar to that as described above using FIG. 18 and FIG. 19. Thus, a detailed description thereof is omitted below.

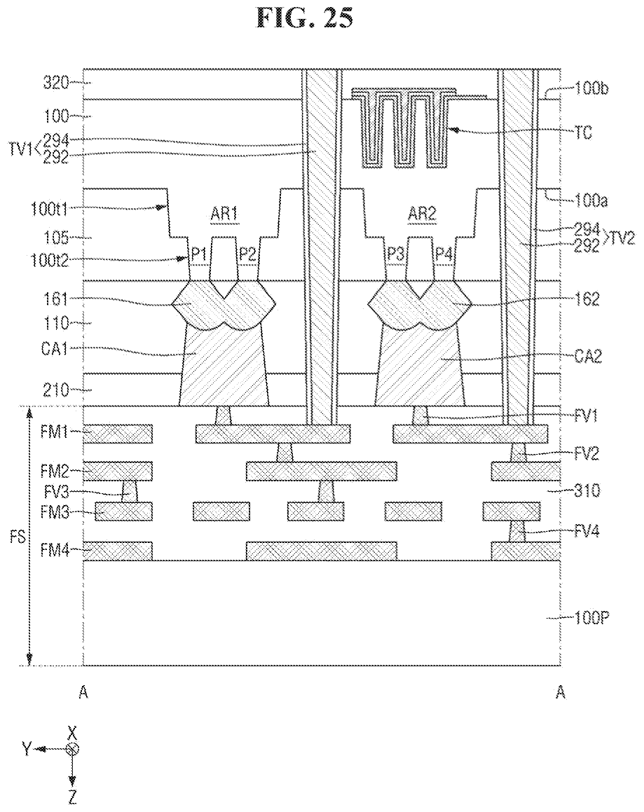

Referring to FIG. 25, the first through-via TV1 and the second through-via TV2 are formed.

For example, the back inter-wiring insulating film 320 may be formed on the second face 100b of the substrate 100. Subsequently, an etching process may be performed on the second face 100b of the substrate 100. Thus, via holes extending in the third direction Z and sequentially extending through the back inter-wiring insulating film 320, the substrate 100, the field insulating film 105, and the interlayer insulating films 110 and 210 may be formed. The first through-via TV1 and the second through-via TV2 may respectively fill the via holes. For example, the through-spacer 294 and the through-conductive film 292 sequentially stacked in each of the via holes may be formed.

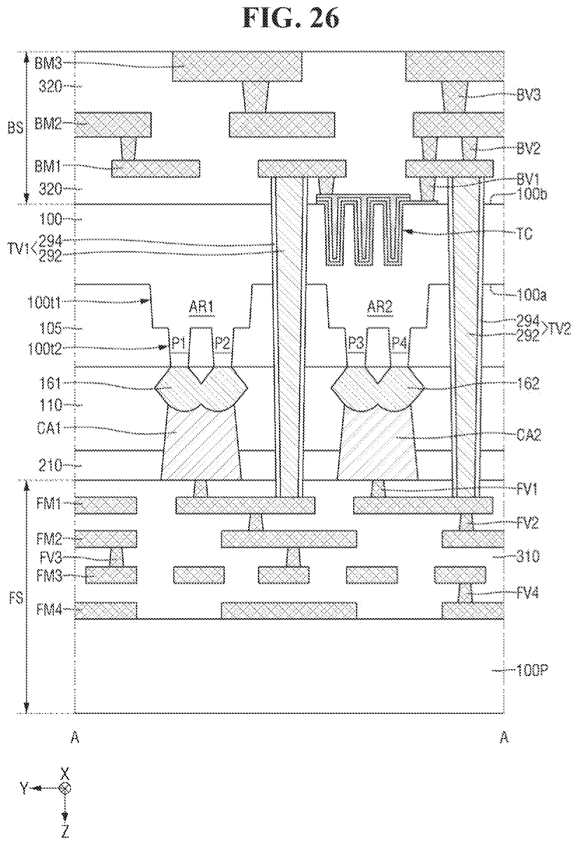

Referring to FIG. 26, the back wiring structure BS is formed on the second face 100b of the substrate 100. Forming the back wiring structure BS is similar to that as described above using FIG. 20. Thus, a detailed description thereof is omitted below.

The carrier substrate 100P may then be removed. Thus, the semiconductor device as described above using FIG. 9 may be manufactured.

While the present inventive concept has been described with reference to exemplary embodiments thereof, it will be understood by those of ordinary skill in the art that various changes in form and details may be made thereto without departing from the spirit and scope of the present inventive concept.

What is claimed is:

1. A semiconductor device comprising:
a substrate including a first face, on which an active area is formed, and a second face opposite to the first face;
an electronic element formed on the active area;
a front wiring structure disposed on the first face of the substrate and connected to the electronic element;
a trench capacitor filling at least a portion of a back trench extending into the substrate from the second face of the substrate;
a back wiring structure disposed on the second face of the substrate and connected to the trench capacitor; and
a through-via extending through the substrate to electrically connect the electronic element and the back wiring structure to each other.

2. The semiconductor device of claim 1, wherein a power voltage is applied to the electronic element via the back wiring structure.

3. The semiconductor device of claim 2, wherein the power voltage is applied to the trench capacitor via the back wiring structure.

4. The semiconductor device of claim 1, wherein the trench capacitor includes a first electrode film and a second electrode film facing each other, and a capacitor dielectric film interposed between the first electrode film and the second electrode film.

5. The semiconductor device of claim 4, wherein one of the first electrode film or the second electrode film is electrically connected to the electronic element.

6. The semiconductor device of claim 1, wherein a width of the through-via decreases as the through-via extends in a direction from the front wiring structure toward the back wiring structure.

7. The semiconductor device of claim 1, wherein a width of the through-via decreases as the through-via extends in a direction from the back wiring structure toward the front wiring structure.

8. The semiconductor device of claim 1, wherein the through-via connects the front wiring structure and the back wiring structure to each other.

9. The semiconductor device of claim 1, wherein the electronic element includes:
An active pattern disposed on the active area;
a gate structure intersecting the active pattern; and
a source/drain area in the active pattern and disposed adjacent to a side surface of the gate structure,
wherein the through-via is electrically connected to the source/drain area.

10. The semiconductor device of claim 9, further comprising a source/drain contact disposed on the side surface of the gate structure, wherein the source/drain contact connects the front wiring structure and the source/drain area to each other.

11. The semiconductor device of claim 10, wherein the through-via is connected to the source/drain contact.

12. A semiconductor device comprising:
a substrate including a first face, on which an active area is formed, and a second face opposite to the first face;
a first electronic element formed on the active area;
a first through-via extending through the substrate to be electrically connected to the first electronic element;
a trench capacitor filling at least a portion of a back trench extending into the substrate from the second face of the substrate; and
a back wiring structure disposed on the second face of the substrate, wherein the back wiring structure electrically connects the first through-via and the trench capacitor to each other,
wherein a first power voltage is applied to the first electronic element and the trench capacitor via the back wiring structure.

13. The semiconductor device of claim 12, wherein the trench capacitor includes a first electrode film and a second electrode film facing each other,
wherein the first power voltage is applied to the first electronic element and the first electrode film via the back wiring structure.

14. The semiconductor device of claim 13, further comprising:
a second electronic element formed on the active area; and
a second through-via extending through the substrate and electrically connected to the second electronic element,
wherein the back wiring structure connects the first through-via and the first electrode film to each other and connects the second through-via and the second electrode film to each other,
wherein a second power voltage different from the first power voltage is applied to the second electronic element and the second electrode film via the back wiring structure.

15. A semiconductor device comprising:
a substrate including a first face, on which a first active area and a second active area are formed, and a second face opposite to the first face;
a first electronic element disposed on the first active area and having a first conductivity type;
a second electronic element disposed on the second active area and having a second conductivity type different from the first conductivity type;
a front wiring structure disposed on the first face of the substrate, and connected to the first electronic element and the second electronic element;
a first through-via extending through the substrate and electrically connected to the first electronic element;
a second through-via extending through the substrate and electrically connected to the second electronic element;
a trench capacitor filling at least a portion of a back trench extending into the substrate from the second face of the substrate, wherein the trench capacitor includes a first electrode film and a second electrode film facing each other; and
a back wiring structure disposed on the second face of the substrate, wherein the back wiring structure connects the first through-via and the first electrode film to each other and connect the second through-via and the second electrode film to each other.

16. The semiconductor device of claim 15, wherein a first power voltage is applied to the first electronic element and the first electrode film, and
wherein a second power voltage different from the first power voltage is applied to the second electronic element and the second electrode film.

17. The semiconductor device of claim 15, wherein each of the first through-via and the second through-via includes a through-conductive film and a through-spacer at least partially surrounding a side surface of the through-conductive film.

18. The semiconductor device of claim 15, wherein a depth of the back trench is about 50% or greater of a thickness of the substrate.

19. The semiconductor device of claim 18, wherein the thickness of the substrate is in a range of about 150 nm to about 700 nm.

20. The semiconductor device of claim 15, wherein a width of each of the first through-via and the second through-via is in a range of about 10 nm to about 100 nm.
